(19) United States
(12) Patent Application Publication
(10) Pub. No.: US 2008/0171285 A1
(43) Pub. Date: Jul. 17, 2008

(54) Immersion Lithography Technique And Product Using A Protection Layer Covering The Resist

(75) Inventors: Kyle Patterson, Froges (FR); Kirk Strozewski, Round Rock, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescales Semiconductor, Inc., Austin, TX (US)

(21) Appl. No.: 10/595,762

(22) PCT Filed: Feb. 15, 2005
(86) PCT No.: PCT/EP05/01511

§ 371 Date: Jul. 13, 2006

(30) Foreign Application Priority Data
Feb. 17, 2004 (EP) 04290429.2

(51) Int. Cl. G03C 1/00; G03F 7/26

(52) U.S. Cl. 430/270.1; 430/322

(57) ABSTRACT

In an immersion lithography method, the photoresist layer is provided with a shield layer to protect it from degradation caused by contact with the immersion liquid. The shield layer is transparent at the exposure wavelength and is substantially impervious to the immersion liquid. The shield layer can be formed of a material which can be removed using the same developer as is used to develop the photoresist layer after exposure.

### FIELD OF THE INVENTION

The present invention relates to the field of optical lithography and, more particularly, to immersion lithography.

### BACKGROUND OF THE INVENTION

Optical lithography (or photolithography) has been used in the semiconductor industry for over 40 years as a mainstay in the manufacture of integrated semiconductor components and the like. Successive improvements in optical lithography have enabled extremely small features to be printed and fabricated. Unfortunately, this technology is starting to come up against physical barriers which tend to limit further reduction in the scale of the features which can be fabricated. Alternative techniques, such as extreme ultraviolet lithography, have been proposed. However, these alternative technologies are not yet ready for use.

The Rayleigh equation defines the minimum line width, LW, that can be printed with optical lithography, as follows:

$$LW = \frac{k λ}{NA}$$

where k is the process factor, λ is the wavelength used in the photolithographic process, and NA is the numerical aperture of the exposure lens system.

The process factor, k, depends upon a number of variables in the photolithography process but is considered to have a practical lower limit of 0.25.

Currently, argon fluoride (ArF) Excimer lasers, with a wavelength of 193 nm, are used in photolithography. Fluorine (F₂) Excimer lasers (λ=157 nm) have also been proposed. Many are reluctant to invest in the equipment needed to use Fluorine (F₂) Excimer lasers (λ=157 nm) given that this equipment is liable to be of use for only a limited period of time. In fact, the recent progress in immersion lithography has caused the vast majority of semiconductor manufacturers to remove 157 nm from their future plans altogether.

It has been suggested that a numerical aperture, NA, as high as 0.93 could be obtained in a photolithographic system in an ArF system (λ=193 nm) which, based on the above Rayleigh equation, would make a line width of 52 nm achievable. In theory, the maximum achievable value for numerical aperture is 1 in systems where air is the medium between the lens and the wafer, giving a smallest-possible line width in ArF systems of just over 48 nm. However, it has been predicted that line widths of 45 nm and below will be required by 2007.

Recently another technique, immersion lithography, has been proposed which can improve the resolution of optical lithography processes down to smaller scales than hitherto. Immersion lithography increases resolution by inserting an immersion medium, generally a liquid, between the optical system used in the photolithographic patterning process and the wafer being processed, in order to increase the numerical aperture of the optical exposure system.

Typically, in a projection exposure system an immersion liquid is inserted between the final lens element and the wafer to be patterned. There are two main approaches: ether the whole wafer stage is flooded with the immersion liquid or a meniscus (a few millimetres thick) is trapped between the final lens element and the wafer.

The numerical aperture, NA, of the optical projection system can be calculated according to the following equation:

NA=η sin θ

where η is the refractive index of the medium between the lens and the wafer and θ is the acceptance angle of the lens. It will be seen that by selecting the inserted medium to have a higher refractive index than air at the exposure wavelength the numerical aperture of the system can be increased.

In the case of immersion lithography using ArF systems (λ=193 nm) the leading candidate for an immersion medium is water, typically de-ionized water. The refractive index of deionized water is 1.44 which, if used as the immersion liquid in an ArF system, would give a potential line width of approximately 33 nm.

However, if a photoresist film is immersed in water many deleterious effects can ensue: leeching of ionic materials from the photoresist film, swelling of the resist, altered diffusion of remaining materials within the resist matrix, etc. These problems are particularly acute in the case of use of de-ionized water. These difficulties are likely to lead to a need to develop new photoresist materials leading to delays in introduction of immersion lithography technology or, at the least, there will be a reduction in the resolution that this technology could achieve.

For immersion media other than water it may also be the case that contact between the immersion liquid and the photoresist will degrade the properties of the photoresist.

It is to be understood that, in the present document, references to an “immersion medium” or “immersion liquid” denote a medium or liquid that is present between the lens and wafer in an optical lithography system. The word “immersion” should not be taken to require that the whole equipment (or even the wafer in its entirety) be immersed or submerged in the medium or liquid in question, although this may occur in some cases.

### DESCRIPTION OF THE PRIOR ART

The paper “Extending optics to 50 nm and beyond with immersion lithography” by M. Switkes et al (Journal of Vacuum Science & Technology B, November/December 2003, American Vacuum Society) discusses immersion lithography and indicates that some resists are inherently suitable for use in immersion lithography processes. However, it also indicates that a problem remains with regard to potential interactions between the immersion medium (notably water) and the photoresist.

In the field of lithography using chemically-amplified resists (CARs), it has been proposed to provide a top coating on the CAR in order to improve the stability of the CAR (increase its shelf life). In this regard see US 2001/044077 and U.S. Pat. No. 5,326,675. These prior proposals do not envisage use of immersion lithography techniques and so often propose water-soluble top coatings.

### SUMMARY OF THE INVENTION

The preferred embodiments of the present invention enable an immersion lithography technique to be applied while substantially avoiding undesirable effects on the photoresist film caused by contact with the immersion medium.

The present invention provides an immersion lithography method as described in the accompanying claims.

The present invention further provides an intermediate product as described in the accompanying claims, adapted for exposure in an immersion lithography process employing a particular immersion medium.

### BRIEF DESCRIPTION OF THE DRAWINGS

The above and other features and advantages of the present invention will become clear from the following description of preferred embodiments thereof, given by way of example, and illustrated by the accompanying drawings, in which:

FIG. 1 is a flow diagram indicating the main steps in an immersion lithography method according to one preferred embodiment of the present invention; and

FIG. 2 is a diagram indicating the structure of the wafer at different stages in the method of FIG. 1.

### DETAILED DESCRIPTION OF THE PREFERRED EMBODIMENTS

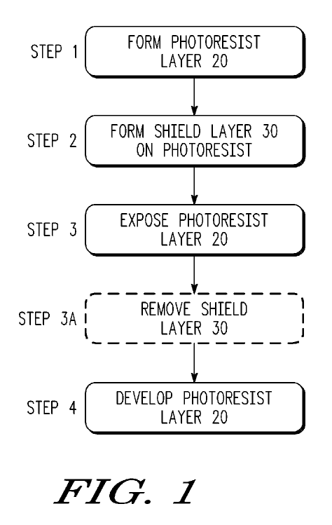

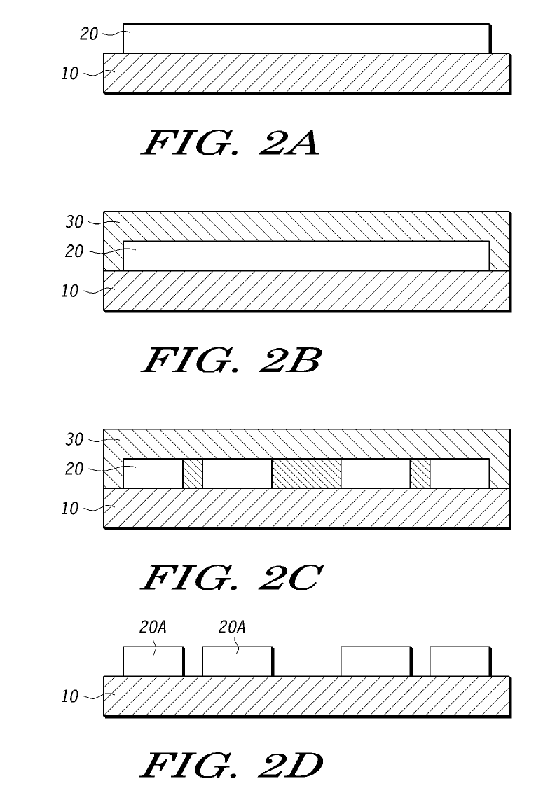

A preferred embodiment of the immersion lithography method according to the present invention will now be described with reference to FIGS. 1 and 2.

As indicated in the flow diagram of FIG. 1, step 1 in the method is the creation of a photoresist layer 20 on a substrate 10. (It is to be noted that the substrate 10 may be a blank wafer or it may have already been subjected to photolithographic patterning to create particular features.) The resultant structure is illustrated schematically in FIG. 2A.

The photoresist layer 20 can be formed on the substrate 10 in any convenient manner. Typically, if the substrate is a wafer, the wafer will first be cleaned and primed, a barrier layer will be formed thereon, the photoresist will be formed thereon by spin coating using well-known techniques, then the photoresist will be soft baked to remove undesirable traces of solvent. Typically at the periphery of the photoresist layer several millimetres of that layer are removed (“edge bead removal”). Details of these processes are well-known to the person skilled in the art and can be found, for example, at the “photolithography” page of the website at http:/www.ee.washington.edu.

Next, as shown at step 2 of FIG. 1, a shield or capping layer 30 is formed over the photoresist layer 20 by any suitable process to yield the structure illustrated in FIG. 2B. Typically, it is convenient to form the shield layer 30 on the photoresist layer using techniques that are employed for forming top anti-reflective coatings (TARC), which will in general include a baking step after coating of the shield layer material.

Advantageously, the shield layer 30 is formed so as to cover substantially all the free surfaces of the photoresist layer, notably the top and side surfaces as shown in FIG. 2B. If edge bead removal is performed subsequent to the formation of the shield layer 30 then, preferably, the amount of removed material is smaller than that removed in the earlier edge bead removal process performed on the photoresist layer 20, so as to ensure that a portion of the shield layer 30 remains covering the side surfaces of the photoresist layer 20.

The substrate 10 bearing the photoresist 20 now protected by the shield layer 30 is aligned relative to an optical lithography exposure system, an immersion medium is provided between the exposure lens and the shield layer 30, and the exposing radiation is switched on (step 3 of FIG. 1). Well-known stepper or scanner devices can be used to displace the substrate 10 relative to the exposing optical system (or vice versa) during the exposure, as necessary.

It will be seen that, according to the preferred embodiment of the present invention, a shield layer is formed over the photoresist layer before contact between the photoresist layer and the immersion medium. The shield layer 30 is formed from a material that is optically transparent at the exposure wavelength and which is substantially impervious to, and preferably substantially insoluble in, the immersion medium. Thus, the exposing radiation exposes the photoresist through the shield layer 30 to yield the structure illustrated in FIG. 2C. Moreover, the shield layer 30 prevents deleterious effects that would otherwise be produced on the photoresist layer 20 by the immersion medium.

By capping the photoresist with a shield layer that is substantially impervious to the immersion medium, the immersion lithography method of the preferred embodiment avoids contact between the photoresist and the immersion medium, thus preventing degradation in the properties of the photoresist. This allows conventional photoresist materials to be used even in the new immersion lithographic processes, enabling a more rapid introduction of this technology.

It is preferred to use for the shield layer 30 a material that is substantially insoluble in the immersion medium. A partially-soluble material could be used, but the solubility of the shield layer material in the immersion medium would need to be sufficiently low to avoid the photoresist layer becoming exposed to the immersion medium before the photolithographic process has been completed. Moreover, if the shield layer material has a rate of dissolution in the immersion medium that is too rapid then there would be a danger that the lens element would become coated in the dissolved shield layer material, inhibiting accurate patterning of the photoresist.

FIG. 2C illustrates the case of a positive photoresist: the dark areas in FIG. 2C represent areas which have been exposed to the exposing radiation, the light areas represent regions which have been hidden from the exposing radiation by the lithographic mask. It is to be understood that the present invention is applicable in general to positive and negative photoresists.

Once the photoresist layer 20 has been exposed, the substrate 10 is removed from the exposure apparatus. In general, the exposed photoresist will now be subjected to a post-baking step. If the shield layer 30 cannot be removed using the developer fluid normally used to develop the exposed photoresist layer 20, then a step 3a is included in the method so as to remove the shield layer. The shield layer 30 can be removed using any suitable chemical agent or physical process which leaves the underlying photoresist substantially unaffected.

Advantageously, the shield layer 30 is formed of a material that can readily be removed using the same developer as is used to develop the exposed photoresist layer 20. Thus, in a single step (step 4 of FIG. 1) the photoresist layer 20 is developed and the shield layer 30 is also removed. This avoids an excessive increase in the number of steps involved in the photolithographic fabrication process and associated increased costs and waste products for disposal.

After the shield layer 30 and photoresist layer 20 have been removed this leaves the substrate 10 bearing patterned photoresist 20a as illustrated in FIG. 2D.

The present invention makes use of the shield layer 30 to protect the resist 20 from the potentially deleterious effects of contact with the immersion medium during immersion lithography. However, use of the shield layer 30 produces an additional beneficial effect. If the shield layer 30 was absent, and the resist 20 were to be exposed during the immersion lithography process then, during exposure of the resist, various species could leach out from the resist. In many cases, these leached materials would contaminate, and even damage, the exposure optics. The exposure optics are costly, representing perhaps 50% of the cost of the overall lithography tool which, in its turn, is one of the most costly items in a semiconductor manufacturing establishment. Accordingly, protection of the exposure optics is an important advantage provided by the present invention.

The material to be used to form the shield layer 30 is chosen dependent on the exposure wavelength and the immersion medium used in the immersion lithography process. A suitable material is one that is transparent at the exposure wavelength and is substantially impervious to (and, preferably, substantially insoluble in) the immersion liquid.

The material used for the shield layer 30 may also be chosen dependent on the developer to be used in developing the photoresist, so that this shield layer material may be removed using the same developer as that used to develop the photoresist after exposure. This cuts down on the overall number of steps required in the lithographic process. Moreover this ensures that the developed photoresist 20a will not be damaged by the process used for removing the shield layer 30.

Clearly, the shield layer material must also be one which itself has substantially no deleterious effects on the photoresist material.

The vast majority of modern photoresists are chemically-amplified resists that can be developed using an aqueous solution of tetramethylammonium hydroxide (TMAH) as the developer solution. This TMAH developer solution is basic (high pH).

When seeking a shield layer material which can readily be removed by the developer, it is relatively straightforward to select a suitable material for use at 157 nm exposure wavelengths because the properties of the typical immersion medium (a fluorinated solvent) are significantly different from those of the typical developer (an aqueous solution of TMAH). Therefore, any polymer that offers high transparency at 157 nm as well as solubility in basic aqueous solutions will likely fulfil the requirements of the shield layer.

However, at 193 nm exposure wavelengths the choice of shield layer material is more difficult because the immersion medium typically is water and the developer typically is an aqueous solution of TMAH. Thus, in the latter case what is required is a shield layer material whose solubility is pH dependent. Examples of suitable shield layer materials for use at this exposure wavelength include a zwitterionic polymer or co-polymer that is optically transparent at 193 nm; a crosslinked polymer film, optically transparent at 193 nm, that is susceptible to rapid base hydrolysis to induce aqueous solubility; etc.

It is to be noted that the present invention is applicable to immersion lithography processes involving non-chemically-amplified photoresists as well as to processes involving chemically-amplified photoresists. Moreover the present invention is not limited with regard to the exposure wavelength (365 nm, 248 nm, 193 nm, 127 nm, etc.) or associated technology (I-line, deep UV, etc.) used in the immersion lithography process. More specifically, the use of optical wavelengths is not a requirement.

To take one specific example, consider the case of an APEX photoresist (proposed by IBM) that is to be exposed in an immersion lithography process performed at 248 nm, in which water is the immersion liquid. It is desired to used an 0.26N TMAH developer solution to develop the photoresist once it is exposed. In such a case, it is advantageous to use for the shield layer a co-polymer of 4-hydrosystyrene and 4-vinylaniline. The nominal structure of this co-polymer is indicated below.

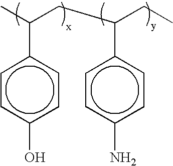

However, this co-polymer does not exist in the nominal form, instead it exists in a zwitterionic form due to acid-based interactions between the monomer units. The zwitterionic form is illustrated below.

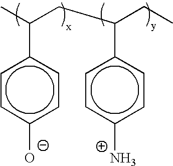

In a neutral pH environment a film formed from this co-polymer is substantially insoluble in and substantially impervious to water. Thus, a film formed of this co-polymer would shield a photoresist from water, in the case where water is used as the immersion liquid in this immersion lithography process.

In a high or low pH environment this co-polymer is soluble. The TMAH developer solution has a relatively high pH and so can remove a film of this co-polymer as well as developing the exposed photoresist.

A shield layer 30 of this co-polymer of 4-hydroxystyrene and 4-vinylaniline can be formed on a photoresist layer 20 by coating the photoresist layer 20 with the oxalate salt of the co-polymer, from water, in a manner similar to that used when forming TARC films (see, for example, “Spin-on application of top-side A/R coatings”, by Brian Head, in Solid State Technology June, 2003). After the oxalate salt has been coated on the photoresist layer 20, a baking step is performed which decomposes the oxalate salt into the water-insoluble co-polymer as illustrated below.

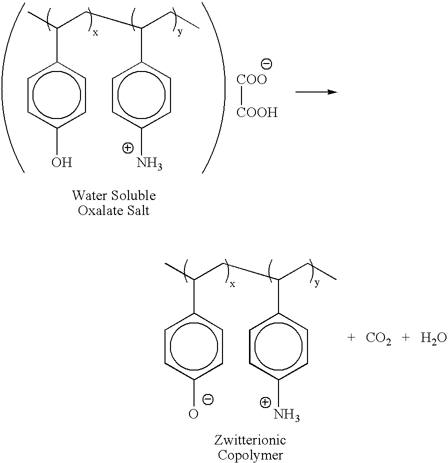

Typically the baking step that decomposes the oxalate salt will involve baking the sample at 150° C. for 60 seconds.

In the above process, it is convenient to prepare the shield layer material initially as an aqueous solution, because this facilitates coating of the photoresist layer 20. After coating, the shield layer material can be converted to a water-insoluble form by any suitable chemical or physical process (during the post-coating baking step in the above example).

The above-mentioned zwitterionic copolymer is not sufficiently transparent to be used at exposure wavelengths of 193 nm or shorter. However, the above-described approach can be extended to shorter wavelengths by replacing the acid and base monomers with alternate monomers that are transparent at the wavelength of interest.

Although the present invention has been described with reference to a preferred embodiment thereof, it is to be understood that the invention is not limited with reference to the details of that embodiment. More particularly, the person skilled in the art will realize that changes and adaptations can be made in that embodiment without departing from the scope of the present invention as defined in the accompanying claims.

For example, the above discussion of photoresists is a simplified one. The skilled person will readily appreciate that the photoresists can contain additional components (such as photoacid generators, photobase generators, quenchers, dissolution inhibitors, amplification catalysts, etc.) that have not been specifically mentioned above.

Similarly, the discussion of the immersion lithography process has been simplified. The skilled person will readily appreciate that additional steps and measures will generally be applied in the immersion lithography process, such as measures to ensure that no bubbles are formed in the immersion liquid, a rinsing step to ensure that developer is rinsed from the developed photoresist, etc.

Moreover, although the above-described preferred embodiment relates to an immersion lithography process in which the immersion medium is water, the present invention is not limited to use of this particular immersion liquid or even to the use of liquids—immersion media in other forms may be used, for example gases.

1. An immersion lithography method in which an optical exposure system is used to expose a photoresist layer during an exposure period;
an immersion medium is inserted between the optical exposure system and the photoresist layer to be exposed; and
after exposure, the photoresist layer is developed using a developer;
characterized in that the method comprises the step of providing the photoresist layer with a shield layer to prevent contact between the photoresist layer and the immersion medium;
said shield layer being transparent at the exposure wavelength and being impervious to the immersion medium.

2. An immersion lithography method according to claim 1, wherein the shield layer is formed of a material that is insoluble in the immersion medium to a degree sufficient to prevent the immersion medium from contacting the photoresist layer during the exposure period.

3. An immersion lithography method according to claim 2, wherein the shield layer is formed of a material that is removed by the developer.

4. An immersion lithography method according to claim 3, wherein the immersion medium is water, the developer is tetramethylammonium hydroxide and the shield layer is formed of a material having pH-dependent solubility.

5. An immersion lithography method according to claim 4, and comprising the step of providing the photoresist layer with the shield layer by coating the photoresist layer with the shield layer material, then applying a chemical or physical process to render the shield layer insoluble in water to a degree sufficient to prevent the water immersion medium from contacting the photoresist layer during the exposure period.

6. An intermediate product adapted for exposure in an immersion lithography process employing a particular immersion fluid;
the product consisting of a substrate bearing a photoresist layer;
characterized in that the surface of the photoresist layer remote from the substrate is covered by a shield layer;
which is transparent at the exposure wavelength used in the immersion lithography process and impervious to said particular immersion medium.

7. The intermediate product of claim 6, wherein the shield layer material is chosen such that it is insoluble in said particular immersion medium to a degree sufficient to prevent the immersion medium from contacting the photoresist layer during the exposure period.

8. The intermediate product of claim 6, wherein the shield layer material is chosen such that a common developer can remove the shield layer and develop the photoresist layer.

9. The intermediate product of claim 8, wherein the shield layer is formed of a material having pH-dependent solubility.

10. The intermediate product of claim 9, wherein said particular immersion medium is water, and the shield layer is formed of a material which is impervious to water.
